(19) United States
(12) Patent Application Publication
(10) Pub. No.: US 2019/0377037 A1
(43) Pub. Date: Dec. 12, 2019

(54) METHOD FOR PROVIDING A MAGNETIC ROTARY SENSOR ENABLED BY SPIN-ORBIT TORQUE AND SPIN CURRENT

(71) Applicant: National University of Singapore, Singapore (SG)

(72) Inventors: Yihong Wu, Singapore (SG); Ziyan Luo, Singapore (SG); Yanjun Xu, Singapore (SG)

(21) Appl. No.: 16/431,317

(22) Filed: Jun. 4, 2019

(30) Foreign Application Priority Data
Jun. 12, 2018 (SG) 10201805003Q

(51) Int. Cl. G01R 33/09; G01R 33/07; G01R 33/00; H01L 43/08; H01L 43/14

(52) U.S. Cl. CPC G01R 33/093; G01R 33/075; H01L 43/14; H01L 43/08; G01R 33/0052

(57) ABSTRACT

In example embodiments, a SOT-based magnetic rotary position sensor includes two spin Hall anomalous Hall effect (SHAHE) sensors, two spin Hall magnetoresistance (SMR) sensors or two unidirectional spin Hall magnetoresistance (USMR) sensors. In embodiments using SHAHE sensors, the sensors may be structured as Hall crosses formed from a film stack including a FM/heavy metal (HM) bi-layer or other SOT-generating layers. The current axes of the Hall crosses are orthogonally aligned. In embodiments using SMR or USMR sensors, the sensors may be structured as Wheatstone bridges including four SMR or USMR sensing elements each formed from a film stack including a FM/HM bi-layer or other SOT-generating layers. The field sensing axes of the Wheatstone bridges are orthogonally aligned.

### RELATED APPLICATIONS

The present application claims priority to Singapore Patent Application No. 10201805003Q, filed by Applicant National University of Singapore on Jun. 12, 2018, the contents of which are incorporated by reference herein in their entirety.

### BACKGROUND

### Technical Field

The current invention relates to rotary position detection and more specifically to designs for spin-orbit torque (SOT)-based magnetic rotary position sensors.

### Background Information

Various types of sensors have been developed and are being used for rotary position detection. Those sensors include Hall effect sensors and various types of magnetoresistance (MR) sensors. Compared to Hall effect sensors, MR sensors are more accurate and energy-efficient, but they tend to be more expensive due to their complex structures.

Conventional MR sensors include anisotropic magnetoresistance (AMR) sensors, giant magnetoresistance (GMR) or spin-valve (SV) sensors, tunnel magnetoresistance (TMR) sensors, and planar Hall Effect (PHE) sensors. In general, AMR, GMR, SV and TMR sensors operate based on detecting a change in longitudinal resistance when subject to an external magnetic field. PHE sensors operate based on detecting a change in transverse resistance in response to an external field. Compared with the other conventional MR sensors, AMR sensors are typically more robust to electrostatic discharge, and easier to manufacture and use. They also generally have better detective properties despite their low output.

The AMR effect has its origin in spin-orbit coupling (SOC), which results in anisotropic scattering of electrons when they travel through magnetic materials. Materials exhibiting a normal AMR effect show a maximum resistivity when the current is parallel to the magnetization direction (ρ_{//}) and a minimum resistivity when the current is perpendicular to the magnetization direction (ρ_{⊥}). At intermediate angles between the current and magnetization direction, the resistivity of an AMR material is given by ρ(θ)=ρ_{⊥}+(ρ_{//}−ρ_{⊥})cos²θ, where θ is the angle between the current and the magnetization direction. When the AMR effect is used in magnetic sensing, the magnetization direction is normally set at 45° with respect to the current direction at zero-field so as to maximize the sensitivity, as may be observed by the first derivative of ρ being maximum when ρ=45°. When used in this configuration, the AMR sensor will respond linearly to an external field when the magnitude of the field is small.

The angular dependence of an AMR effect has been exploited for detection of angular positions. In a typical configuration, an in-plane magnetized permanent magnet is attached to a rotation shaft to generate a rotating in-plane field. AMR sensors are placed under the rotating field to detect the magnetic field direction, thereby determining the angular position of the rotational device attached to the shaft.

For each AMR sensor, current may flow between one pair of electrodes of the sensor, and the voltage change caused by an external field may be detected between another pair of electrodes of the sensor. The orientation of one sensor may be set such that it generates a voltage signal proportional to sin (2ϕ), where ϕ is the angle between the current and the external field direction. This is possible when the external field is strong enough to saturate the magnetization in the field direction. The orientation of the other sensor may be 45° away, such that it generates a voltage signal proportional to cos (2ϕ) when subjected to the same rotational field. The output signals evolve two periods when ϕ changes by 360°; therefore, it is only possible to determine rotary position up to 180° unambiguously. In order to resolve 360°, typically an additional sensor must be used to measure the field direction, adding to complexity and manufacturing expense.

A typical GMR sensor consists of two ferromagnetic (FM) layers separated by a non-magnetic spacer and an antiferromagnetic (AFM) layer in contact with one of the FM layers. The thickness of the spacer may be chosen such that there is little exchange coupling between the two FM layers. The magnetization of one of the FM layers that is in direct contact with the AFM layer is pinned by the latter, and thus this FM layer is commonly called a “pinned” layer. The magnetization of the other FM layer is free to rotate to respond to an external field, and thus it is commonly called a “free” layer. The exchange bias between the AFM and FM sets the direction between the magnetizations of the free and pinned layer at 90° at zero-field. This is to ensure that the sensor will respond to external field linearly. When being used, a constant current is applied to the sensor and the voltage change caused by external field is detected. The output signal is proportional to sin(ϕ), where ϕ is the angle between the magnetization of the free layer and that of the pinned layer.

A TMR sensor typically has the same structure as that of a GMR sensor. The main difference is that, in the case of TMR, the non-magnetic layer is replaced by an insulator. In addition, instead of flowing in-plane, current flows vertically with respect to the layers. Again, the output signal is proportional to sin(ϕ), where ϕ is the angle between the magnetization of the free layer and that of the pinned layer.

From the angle dependence of output signal, it is apparent that both GMR and TMR sensors can be used for rotary position detection as long as the external field is able to saturate the magnetization of the free layer without disturbing the magnetization of the reference layer. As with the case of rotary position detection using AMR sensors, multiple GMR or TMR sensors may be placed under the rotating field to detect the magnetic field direction, thereby determining the angular position of a rotational device. With GMR and TMR sensors, it may be possible to determine the angle unambiguously up to 360°, without the need for additional sensors to determine field direction. However, additional processes are typically required to set and align the pinning directions of individual sensors, which significantly increases manufacturing and implementation costs for GMR and TMR sensors. Further, the magnetization of the reference layer may be changed by thermal effect after the sensor has been used for some time in a hush environment.

Accordingly, there remains a need for a magnetic rotary position sensor that may achieve high detection accuracy while being relatively simple and cost effective to manufacture.

### SUMMARY

In example embodiments, a SOT-based magnetic rotary position sensor includes two spin Hall anomalous Hall effect (SHAHE) sensors, two spin Hall magnetoresistance (SMR) sensors or two unidirectional spin Hall magnetoresistance (USMR) sensors. In embodiments using SHAHE sensors, the sensors may be structured as Hall crosses formed from a film stack including a FM/heavy metal (HM) bi-layer or other SOT-generating layers. The current axes of the Hall crosses are orthogonally aligned. In embodiments using SMR or USMR sensors, the sensors may be structured as Wheatstone bridges including four SMR or USMR sensing elements each formed from a film stack including a FM/HM bi-layer or other SOT-generating layers. The field sensing axes of the Wheatstone bridges are orthogonally aligned. In such an arrangement of two SHAHE, SMR or USMR sensors, one of the sensors may produce a sine-like waveform and the other a cosine-like waveform, when the sensors are subject to an external rotating magnetic field parallel (in-plane) to the layers (e.g., caused by a magnet attached to a shaft of a rotational device, such as a motor). The sine-like waveform and the cosine-like waveform complete a single period when the in-plane magnetic field rotates by 360°. The angle of the rotational device can be readily calculated (e.g., by circuitry), by applying appropriate algorithms to the sine-like and cosine-like waveforms. Such a SOT-based magnetic rotary position sensor may achieve high detection accuracy while being more efficient and cost effective to manufacture and implement than conventional sensor designs, among other advantages.

It should be understood that a variety of additional features and alternative embodiments may be implemented other than those discussed in this Summary. This Summary is intended simply as a brief introduction to the reader, and does not indicate or imply that the examples mentioned herein cover all aspects of the disclosure, or are necessary or essential aspects of the disclosure.

### BRIEF DESCRIPTION OF THE DRAWINGS

The description below refers to the accompanying drawings of example embodiments, of which:

FIG. 1 is a diagram of an example SOT-based magnetic rotary position sensor;

FIG. 2 is diagram of an orthogonal configuration of the two Hall crosses on a substrate;

FIG. 3A is a diagram of a first example film stack that includes a FM/HM bilayer structure;

FIG. 3B is a diagram of a second example film stack that includes additional layers;

FIG. 4A is a diagram illustrating inducement of SOT effective field by a charge current and generation of an output signal due to planar Hall effect (PHE) in an example FM/HM bilayer structure, here a Pt/Co bilayer;

FIG. 4B is a graph showing example simulated differential transverse voltage due to anti-damping effective field as a function of field angle with respect to current direction;

FIG. 4C is a graph showing example simulated differential transverse voltage due to field-like effective field as well as Oersted field;

FIG. 5 is a diagram of an example SOT-based magnetic rotary position sensor showing sensor elements structured as a Hall cross;

FIG. 6A is a graph of the absolute value of the Hall voltage signal obtained at ±5 mA for a first Hall cross as a function of in-plane field direction;

FIG. 6B is a graph of the absolute value of Hall voltage signal obtained at ±5 mA for a second Hall cross as a function of in-plane field direction;

FIG. 6C is a graph of differential Hall voltage (ΔV₁) for the first Hall cross;

FIG. 6D is a graph of differential Hall voltage (ΔV₂) for the second Hall cross;

FIG. 7 is a diagram of an example SOT-based magnetic rotary position sensor where each sensor is a SMR sensor structured as a Wheatstone bridge with four SMR sensing elements;

FIG. 8 is diagram of an orthogonal configuration of the Wheatstone bridges having four SMR sensing elements on a substrate; and

FIG. 9 is a graph showing an output waveform of a first Wheatstone bridge of a SMR-based rotary position sensor.

### DETAILED DESCRIPTION

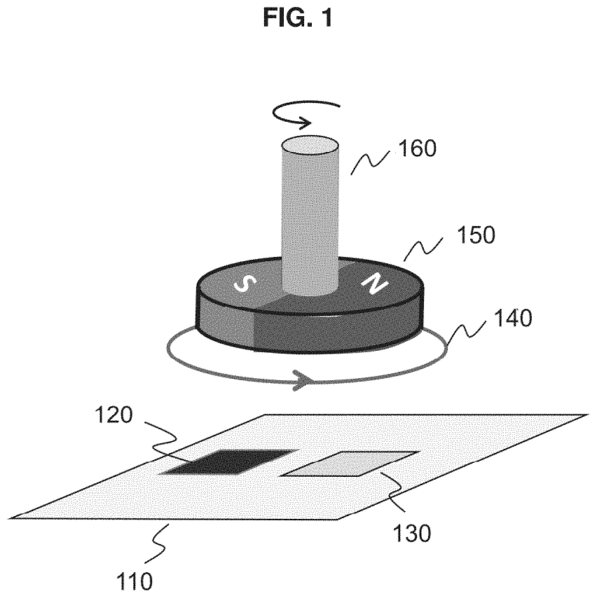

FIG. 1 is a diagram of an example SOT-based magnetic rotary position sensor. An in-plane magnetized permanent magnet 150 that generates a rotating in-plane external field 140 is attached to a shaft 160. The shaft 160 may be coupled to a rotational device, such as a motor (not shown), whose rotary position (angle) is to be measured. Two sensors 120, 130 formed on a substrate 110 are placed under the rotating external field 140. Circuitry (not shown) drives current to the sensors 120, 130 and analyzes voltage change caused by the external field to determine rotary position (angle). In various embodiments, the sensors 120, 130 may be SHAHE sensors, SMR sensors or USMR sensors. In embodiments using SHAHE sensors, the sensors 120, 130 may be structured as Hall crosses formed from a film stack including a FM/HM bi-layer or other SOT-generating layers. The current axes of the Hall crosses are orthogonally aligned. In embodiments using SMR or USMR sensors, the sensors 120, 130 may be structured as Wheatstone bridges including four SMR or USMR sensing elements each formed from a film stack including a FM/HM bi-layer or other SOT-generating layers.

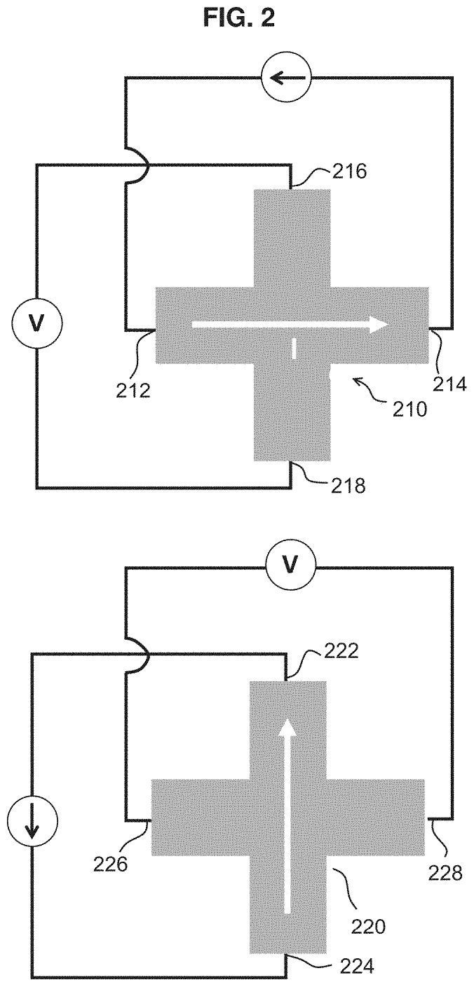

Consider first an embodiment where the sensors 120, 130 are SHAHE sensors that each include a Hall cross, and the current axes of the Hall crosses are orthogonally aligned. FIG. 2 is diagram of an orthogonal configuration of the two Hall crosses 210, 220 on a substrate. Each Hall cross 210, 220 is provided with two current electrodes 212, 214, 222, 224 the path between which defines a current axis, and two voltage electrodes 216, 218, 226, 228 the path between which defines a voltage axis. As can be seen, the Hall crosses 210, 220 are arranged on the substrate such that the current axes are orthogonal to each other.

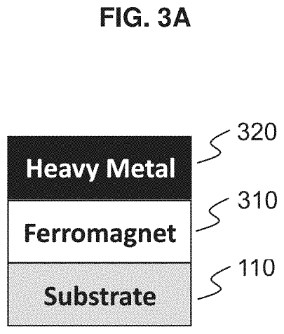

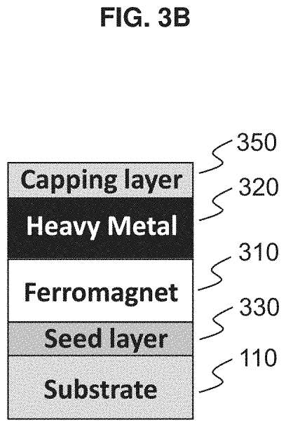

Each Hall cross 210, 220 includes a stack of ultrathin films. Such films may have a number of different configurations, depending on the implementation. FIG. 3A is a diagram of a first example film stack that includes a FM/HM bilayer structure. In this example, a FM layer 310 with in-plane anisotropy is deposited upon the substrate 110, and a HM layer 320 is deposited thereon. The FM layer may include a material such as cobalt (Co), iron (Fe), nickel (Ni), Cobalt-iron-boron (CoFeB), gadolinium (Gd), yttrium-iron-garnet (YIG), a ferrite, and/or alloys comprising Co, Fe, Ni, CoFeB or Gd. The HM layer may include a material such as platinum (Pt), palladium (Pd), tantalum (Ta), tungsten (W), lead (Pb), niobium (Nb), a topological insulator, a transition metal dichalcogenide (TMD) and/or a Weyl metal or semimetal. FIG. 3B is a diagram of a second example film stack that includes additional layers. In this example, an additional seed layer 330 and capping layer 350 are provided. The seed layer 330 may improve both the adhesion of the films to the substrate 120 and the magnetic properties of the FM layer 310.

The film stack (e.g., FM/HM bilayer structure) is capable of generating SOT. SOT is a promising mechanism for magnetization switching and related applications. It is generally accepted that two types of torques are present in a FM/HM bilayer: one commonly referred to as the field-like (FL) torque and the other commonly referred to as the (anti)damping-like (DL) torque. The two types of torques can be modelled by \vec{T}_{DL}=−τ_{DL}\vec{m}×[m\vec{m}×(\vec{j}×\vec{z})] and \vec{T}_{FL}=−τ_{FL}\vec{m}×(\vec{j}×\vec{z}), respectively, where \vec{m} is the magnetization direction, j is the in-plane current density, \vec{z} is the interface normal, and τ_{FL} and τ_{DL} are the magnitude of the FL and DL torques, respectively. If \vec{m}. does not change significantly, the two toques can be expressed in the form of \vec{M}×\vec{H}_{eff}, where \vec{H}_{eff} is an effective field. Following this notion, the FL effective field (\vec{H}_{FL}) is in the direction of −\vec{j}×\vec{z}, whereas the DL effective field (\vec{H}_{DL}) is in the direction of −\vec{m}×(\vec{j}×\vec{z}) (note: the sign can be different depending on the stacking order of HM and FM with respect to the coordinate axes).

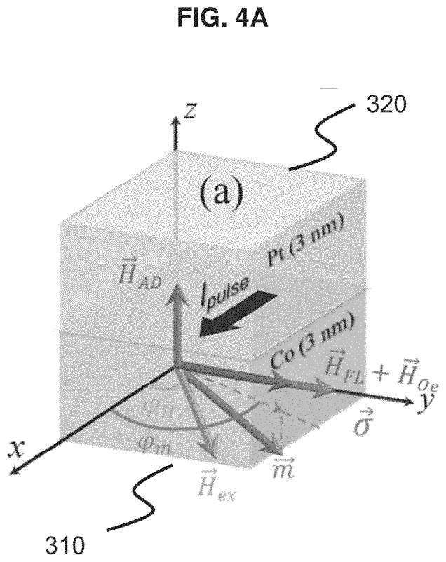

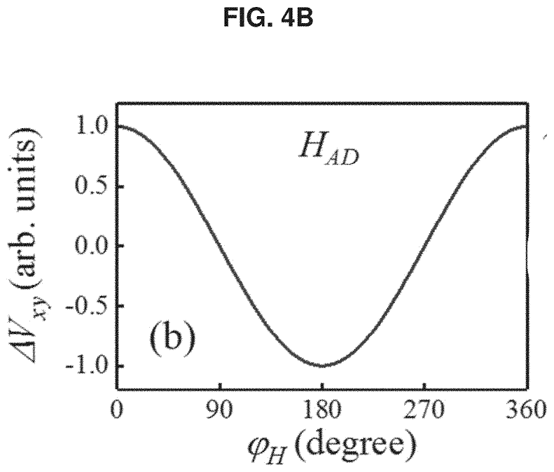

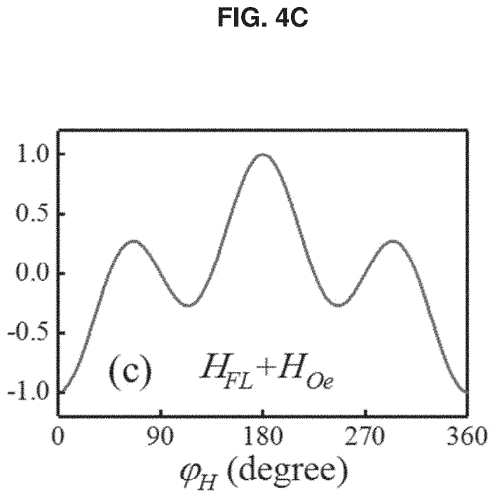

FIG. 4A is a diagram illustrating inducement of SOT effective field by a charge current and generation of an output signal due to planar Hall effect (PHE) in an example FM/HM bilayer structure, here a Pt/Co bilayer 320/320. As shown in FIG. 4A, for a HM/FM bilayer with in-plane magnetic anisotropy, the DL effective field, \vec{H}_{DL}, causes an out-of-plane tilt of the magnetization, inducing a voltage due to anomalous Hall effect (AHE); while the field-like effective field \vec{H}_{FL}, together with the Oersted field \vec{H}_{Oe} from the current in Pt layer, rotates the magnetization in the sample plane, generating a signal due to PHE.

The change of AHE and PHE signal induced by the SOT effective fields can be derived analytically by assuming (1) the effective field is much smaller than the externally applied field \vec{H}ₑₓ and (2) both the in-plane magnetic and shape anisotropy of the FM layer can be neglected. The former allows one to evaluate the influence of effective field using first order approximation, whereas the latter makes it possible to decompose the effective field into different components and calculate their effects on magnetization separately. Based on these assumptions, the Hall voltage can be written as V_{xy}=V_{xy}(\vec{H}ₑₓ)+ΔV_{xy}(\vec{H}ₗ), where \vec{H}_{I}=\vec{H}_{FL}+\vec{H}_{DL}+\vec{H}_{Oe} is the sum of SOT effective field and Oersted field \vec{H}_{Oe}. When the applied external field is in-plane, and both in-plane magnetic and shape anisotropy can be neglected, one may assume θₘ≈θ_{H}=π/2 and φₘ≈φ_{H}. Under these approximations, the differential output signal from pulsed current measurement is given by:

$$Δ {V}_{xy} ( {\vec{H}}_{I} ) = ( {V}_{AHE 0} \frac{{H}_{AD}}{{H}_{ex} + {H}_{d}} ) cos {ϕ}_{H} + ( {V}_{PHE 0} \frac{{H}_{FL} + {H}_{Oe}}{{H}_{ex}} ) ( cos {ϕ}_{H} + cos 3 {ϕ}_{H} ) \qquad ( 1 )$$

where V_{AHE0} and V_{PHE0} are the half peak-to-peak voltage of AHE and PHE, respectively, φ_{H} is the in-plane field angle with respect to x axis, and H_{d} is the demagnetizing field.

It is apparent from Eq. (1) that when the PHE is negligibly small, a Hall cross including a FM/HM bilayer structure functions as an angular position sensor as ΔV_{xy}(\vec{H}ᵢ) ∝cosφ_{H}. The advantage of using a SOT Hall device is that, any offset in the device can be readily compensated by measuring the AHE first using a positive current (+I) followed by a negative current of same magnitude (−I) and then adding up the two measurement results to generate the output signal. This is possible because V_{AHE} is an even function, whereas the offset voltage is an odd function of the driving current. The output signal is simply double of that of the single measurement.

FIG. 4B is a graph showing example simulated differential transverse voltage due to anti-damping effective field as a function of field angle with respect to current direction. FIG. 4C is a graph showing example simulated differential transverse voltage due to field-like effective field as well as Oersted field. When the PHE signal is small, it can be subtracted out from the total measured signal so as to compute the angle φ_{H} from the AHE signal.

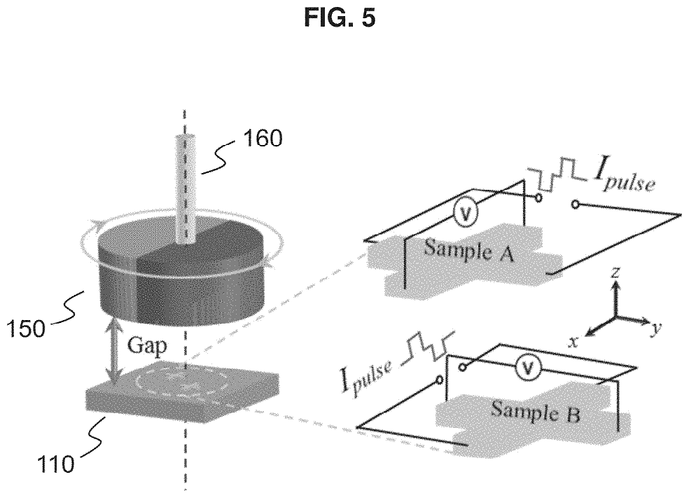

FIG. 5 is a diagram of an example SOT-based magnetic rotary position sensor showing each sensor element structured as a Hall cross 210, 220. In order to resolve the full range of 360°, two identical Hall crosses 210, 220 are used with their current axes aligned orthogonal to each other. In this example, the two Hall crosses 210, 220 have a width of 5 μm and a length of 50 μm. They are placed as close as possible on a same substrate 110. In this example, the film stack of each Hall cross includes a Pt (e.g., of 3 nm thickness)/Co(e.g., of 3 nm thickness) bilayer deposited on a silicon oxide (SiO₂)/silicon (Si) substrate 110 by magnetron sputtering, with a base pressure of 2×10⁻⁸ Torr and working pressure of 3×10⁻³ Torr. Both the current and voltage electrodes are formed of Ta (e.g., of 5 nm thickness)/copper (Cu)(e.g., of 200 nm thickness)/Pt(e.g., of 10 nm thickness) layers. A rotating in-plane magnetic field of 1000 Oe is applied. A current pulse (Iₚᵤₗₛₑ) injected in the x direction for the first Hall cross 210 and the y direction for the second Hall cross 220. Meanwhile, for each polarity of the current pulse, the transverse voltage is recorded as V₊ for positive current and V₋ for negative current. The pulse width of current Iₚᵤₗₛₑ is 5 ms. The measurements are repeated ten times at each angle position to obtain an average voltage signal with low noise. The differential voltage signal ΔV=|V₊|−|V₋| is then extracted as a function of the direction of in-plane magnetic field, ranging from 0° to 360°.

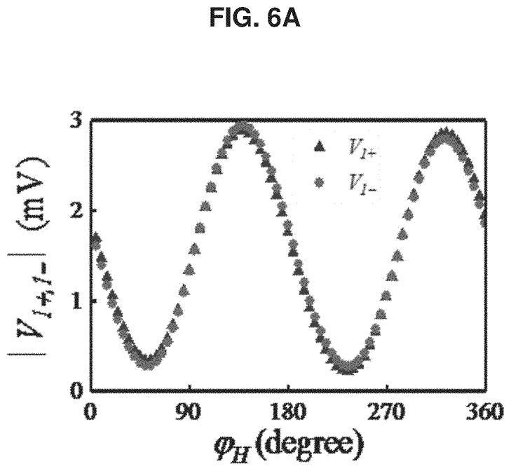

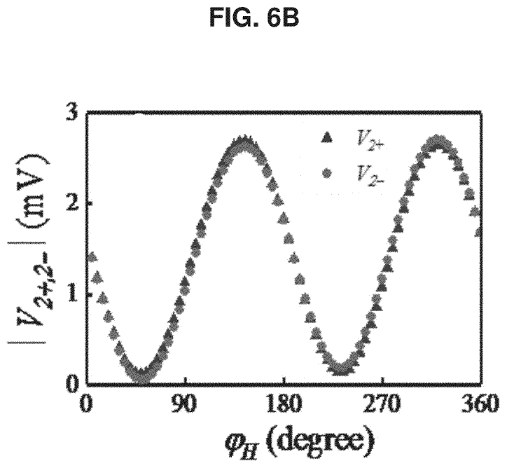

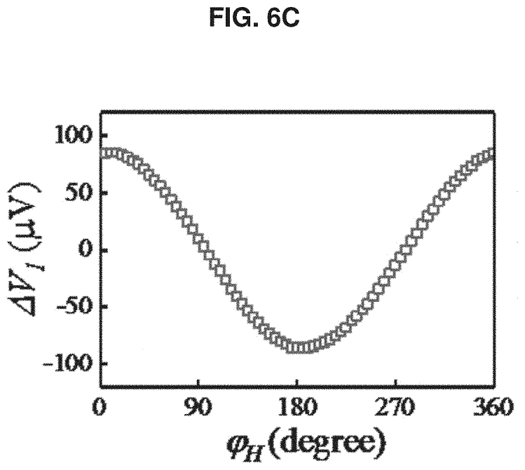

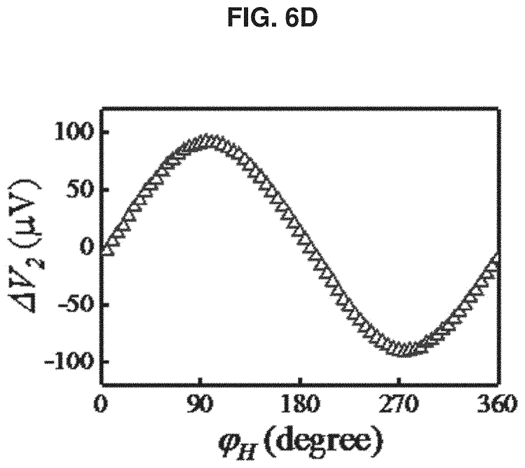

FIG. 6A is a graph of the absolute value of the Hall voltage signal obtained at ±5 mA for the first Hall cross 210 as a function of in-plane field direction, for the above described example. FIG. 6B is a graph of the absolute value of Hall voltage signal obtained at ±5 mA for the second Hall cross 220 as a function of in-plane field direction, for the above described example. The corresponding differential voltage signals (ΔV₁, ΔV₂) may be extracted. FIG. 6C is a graph of differential Hall voltage (ΔV₁) for the first Hall cross 210, for the above described example. FIG. 6D is a graph of differential Hall voltage (ΔV₂) for the second Hall cross 220, for the above described example. As can be seen, ΔV₁ exhibits a cosine-like waveform whereas ΔV₂ exhibits a sine-like waveform, resulting from the perpendicular alignment of the current axis for the two Hall crosses 210, 220. The slight deviation from the exact cosine or sine shape is due to the fact that the measured differential Hall voltage contains both AHE and PHE contributions, as indicated by Eq. (1). After the PHE contribution is subtracted out, nearly pure sine and cosine waveforms may be obtained, which may then be used to calculate angle, e.g., by attached circuitry, by applying an arctan 2 function.

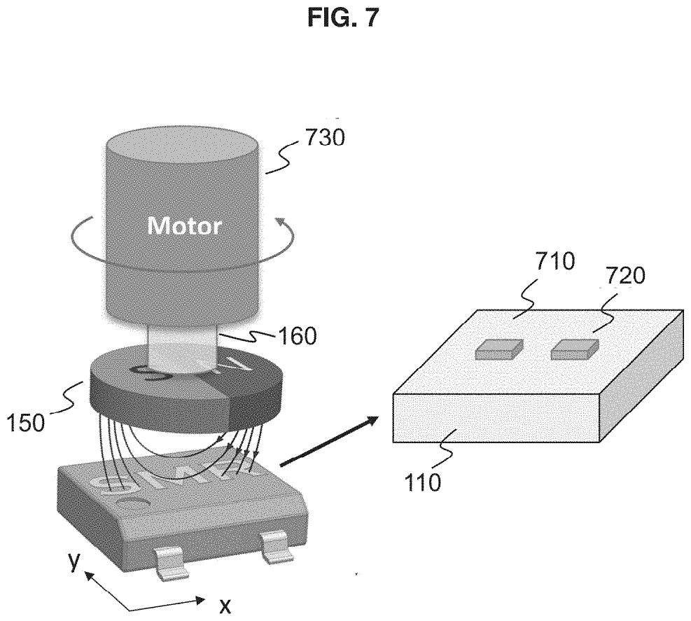

In a second embodiment, each sensor 120, 130 may be a SMR sensor that is structured as a Wheatstone bridge. FIG. 7 is a diagram of an example SOT-based magnetic rotary position sensor where each sensor is a SMR sensor structured as a Wheatstone bridge 710, 720 with four SMR sensing elements. The Wheatstone bridges 710, 720 each detect the direction of the magnetic field generated by a magnet 150 attached to the shaft 160 coupled to a rotational device, for example, a motor 730. The Wheatstone bridges 710, 720 are aligned such that their field sensing axes are orthogonal to each other.

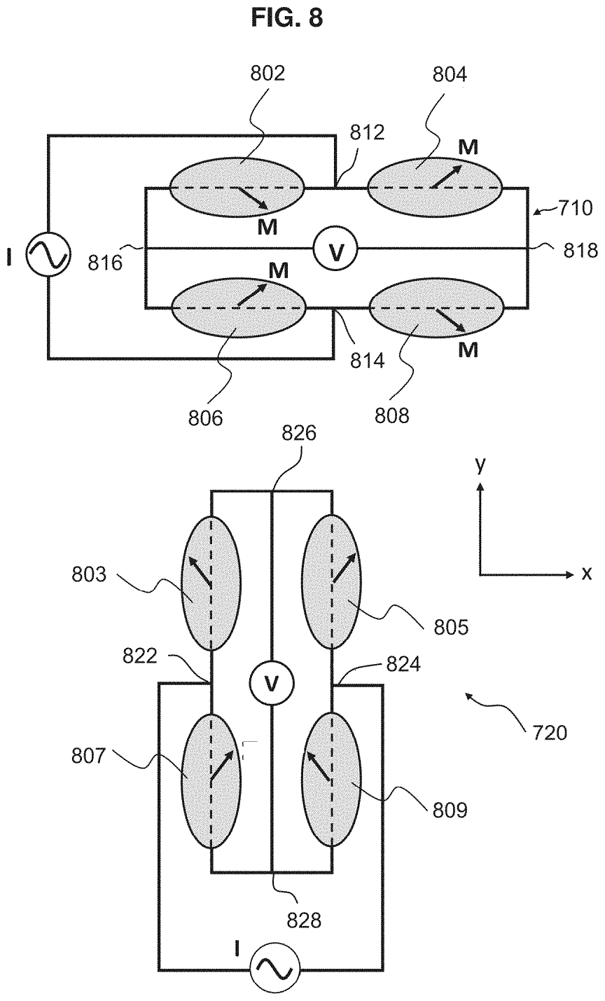

FIG. 8 is diagram of an orthogonal configuration of the Wheatstone bridges 710, 720 having four SMR sensing elements 802-809 on a substrate. Each of the SMR sensing element 802-809 includes a film stack with in-plane magnetic anisotropy that is able to generate SOT when a charge current flows through it. Each Wheatstone bridges 710, 720 has two sense/bias electrodes 812, 814, 822, 824 used to supply a sense/bias current, and the path between them defines a field sensing axis. The charge current is an alternating current with an adjustable DC offset. As can be seen, the Wheatstone bridges 710, 720 are arranged on the substrate 110 such that field sensing axes are orthogonal to each other. Each Wheatstone bridge 710, 720 also has two voltage electrodes 816, 818, 826, 828 used to detect the voltage change caused by the external field. The time-average of the voltage at the two voltage electrodes are detected as the output signal. The DC offset of the sense/bias current may be set such that the DC offset of the output signal is nearly zero. The output signal is used by circuitry (not shown) to determine rotatory position (angle), using either a DC component or 2^{nd} harmonic of the voltage change.

The film stack of each SMR sensing element 802-809 may include a FM/HM bilayer structure. The FM layer may include a material such as Co, Fe, Ni, CoFeB, Gd, YIG, a ferrite, and/or alloys comprising Co, Fe, Ni, CoFeB or Gd. The HM material may include a material such as Pt, Pd, Ta, W, Pb, Nb, a topological insulator, a TMD and/or a Weyl metal or semimetal. When an AC current I=I₀ sinωt passes through a sensing element 802-809 including a FM/HM bilayer, the voltage across the two ends of the sensing element can be derived as follows:

$$V = ( {I}_{o} {R}_{0} + {I}_{o} Δ R ) sin ω t - \frac{{I}_{o} Δ R}{{( {H}_{D} + {H}_{K} )}^{2}} {H}_{y}^{2} sin ω t - \frac{{I}_{o} Δ R}{{( {H}_{D} + {H}_{K} )}^{2}} ( {H}_{y} α {I}_{o} - {H}_{y} α {I}_{o} cos 2 ω t + \frac{3}{4} {α}^{2} {I}_{o}^{2} sin ω t - \frac{1}{4} {α}^{2} {I}_{o}^{2} sin 3 ω t ) \qquad ( 2 )$$

The time-average of V, or DC component, is given by:

$$\overline{V} = \frac{α {I}_{o}^{2} Δ R}{{( {H}_{D} + {H}_{K} )}^{2}} {H}_{y} \qquad ( 3 )$$

where I₀ is the amplitude of applied AC current, ω is the angular frequency, α is the ratio of SOT effective field over applied current, H_{FL}=αI₀ sinωt, ΔR is magnetoresistance, Rₒ is resistance of sensing element, H_{K} is the uniaxial anisotropy field, H_{D} is the shape anisotropy field, H_{y} is the applied field, and θ is the angle between magnetization (M) and easy axis direction. θ can be determined by the energy minimization method and is given by

$$= \frac{{H}_{y} + {H}_{FL}}{{H}_{D} + {H}_{K}} .$$

It is clear from Eq. (3) that, although the sense current is an AC current, the output signal has a DC component that is proportional to the external magnetic field in the y-direction. This means that the sensor exhibits a linear response to external field without the requirement that θ must be 45° at H_{y}=0. This is in sharp contrast to DC biasing in which θ must be set at 45° at H_{y}=0 in order to ensure a linear response of the sensor. Alternatively, the sensor output can also be obtained by detecting the 2^{nd} harmonic of the signal given by Eq. (1), for example using a lock-in technique.

In the case of a Wheatstone bridge 710, 720, when an AC current I=lₒ sinωt passes through two electrodes, the voltage across the other two electrodes is derived as:

$${V}_{out} = \frac{1}{2} {I}_{o} Δ {R}_{0} sin ω t + \frac{1}{2} \frac{α {I}_{0}^{2} Δ {RH}_{y} cos ω t}{{( {H}_{D} + {H}_{K} )}^{2}} - \frac{1}{2} \frac{α {I}_{0}^{2} Δ {RH}_{y}}{2 {( {H}_{D} + {H}_{K} )}^{2}} \qquad ( 4 )$$

where ΔR₀ is the offset resistance caused by non-identical SMR sensing elements due to manufacturing processes, and the remaining parameters are the same as those used in Eq. (2) and (3). The time-average of V, or DC component, is given by:

$$\overline{V} = \frac{1}{2} \frac{α {I}_{o}^{2} Δ R}{{( {H}_{D} + {H}_{K} )}^{2}} {H}_{y} \qquad ( 5 )$$

Again, it is clear from Eq. (5) that, although the sense current is an AC current, the output signal has a DC component which is proportional to the external magnetic field. This means that the sensor exhibits a linear response to external field without the requirement that θ must be 45° at H_{y}=0. Compared to the case of a single sensing element, a Wheatstone bridge configuration leads to a sensor with much smaller AC noise as the large AC signal due to the resistance of each sensing element has been cancelled out. It has also has a smaller DC offset and thermal drift. The DC offset, if any, can be further reduced by adding a DC offset to sense/bias current. Alternatively, lock-in detection may be employed to detect the 2^{nd} harmonic which is also proportional to the external field.

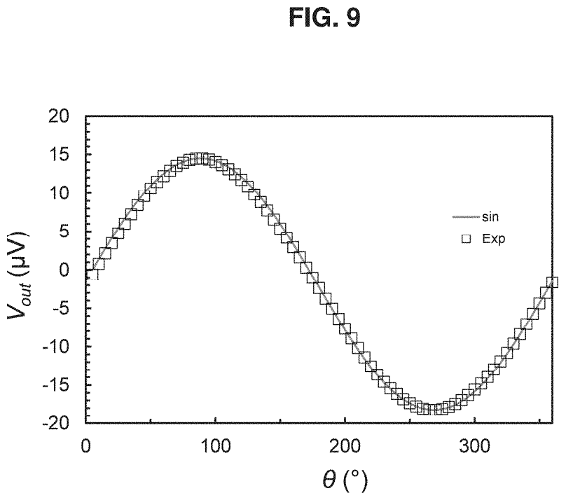

Since the output voltage is proportional to H_{y} when H_{y} is small, when a magnetic field with constant amplitude is rotation in the xy plane, a sine-like waveform is generated from the first Wheatstone bridge 710 and a cosine-like waveform is generated from the second Wheatstone bridge 720. FIG. 9 is a graph showing an output waveform of a first Wheatstone bridge 710 of a SMR-based rotary position sensor. Symbols are output data points while the solid-line is a fitted sine function. The output waveform of the second Wheatstone bridge 720 will appear similar, but cosine-like.

Once the outputs of the first Wheatstone bridge 710 and second Wheatstone bridge 720 are obtained, circuitry may calculate the field angle by applying an acctan 2 function, for example as arctan 2 (output of Wheatstone bridge 710/Wheatstone bridge 720). Pre-calibration may be performed to compensate for deviation (if any) from ideal sine or cosine curves so as to reduce the angle error.

In some implementations, a magnetic shield (not shown) may be used to reduce the field generated by the magnet 150, such that the field will be within the operation range of the SMR sensors. By doing so, the effect of environmental field can be effectively suppressed.

In a third embodiment, each sensor 120, 130 may be a USMR sensor that includes a Wheatstone bridge formed from for USMR sensing elements. Again, the Wheatstone bridges each detect the direction of the magnetic field generated by a magnet attached to the shaft, coupled to a rotational device, for example, a motor, similar to as in FIG. 7. The Wheatstone bridges are aligned such that their field sensing axes are orthogonal to each other. Each of the USMR sensing elements includes a film stack with in-plane magnetic anisotropy, which is able to generate a SOT when a charge current flows through it. Again, each Wheatstone bridges has two sense/bias electrodes used to supply a sense/bias current, and the path between them defines a field sensing axis Likewise, each Wheatstone bridge has two voltage electrodes used to detect the voltage change caused by the external field. The time-average of the voltage at the two voltage electrodes may be detected as the output signal. The DC offset of the sense/bias current may be set such that the DC offset of the output signal is nearly zero. Again, the output signal is used to determine rotatory position (angle) based on either a DC component or 2^{nd} harmonic of the voltage change. Once the outputs of the first Wheatstone bridge and second Wheatstone bridge are obtained, circuitry may calculate the field angle by applying an acctan 2 function. Pre-calibration may be performed to compensate for deviation (if any) from ideal sine or cosine curves so as to reduce the angle error.

The film stack of each USMR sensing element may include a FM/HM bilayer structure. The FM layer may include a material such as Co, Fe, Ni, CoFeB, Gd, YIG, a ferrite, and/or alloys comprising Co, Fe, Ni, CoFeB or Gd. The HM material may include a material such as Pt, Pd, Ta, W, Pb, Nb, a topological insulator, a TMD and/or a Weyl metal or semimetal. When charge current flows through the bilayer, spin current is generated in the HM layer due to spin Hall effect. The spin current diffuses into the FM layer, causing an additional interfacial resistance that is sensitive to the magnetization direction of the FM layer with respect to the spin polarization direction. This gives a USMR, which is a sinusoidal function of the angle between the magnetization direction of the FM layer and the spin polarization direction of the spin current.

In alternative implementations, each USMR sensing element may be formed from a single material with unique spin texture on the surface, such as topological insulators or Weyl metal or semimetal. In still other alternative implementations, each USMR may be an antiferromagnet.

In summary, various embodiments of the present disclosure describe a SOT-based magnetic rotary position sensor. Depending on the embodiment, the sensor may include SHAHE Hall crosses, Wheatstone bridges formed from SMR sensing elements or Wheatstone bridges formed from USMR sensing elements. It should be understood that numerous adaptations and modifications may be made to the above-discussed embodiments without departing from the disclosures intended spirit and scope.

For example, while it is discussed above that a SHAHE Hall cross, SMR sensing elements or USMR sensing elements may include a FM/HM bilayer that generates SOT, it should be understood that other SOT-generating layer structures may alternative be used. For example, a FM/normal-metal (NM)/HM trilayer may be instead used. In such an alternative embodiment, the NM layer may be, for example, silver (Ag), copper (Cu), gold (Au) or another material, and the HM layer may be, for example, bismuth (Bi), bismuth oxide, a topological insulator, or another material. In such an alternative embodiment, the spin orbit torque effect may be generated from both the spin Hall and/or Rashba-Edelstein effect. In other alternative embodiments, an antiferromagnet (AFM)/HM bilayer, a FM/AFM/HM trilayer, an AFM/HM/FM trilayer, an AFM/FM/HM trilayer, or a HM/AFM/FM trilayer may be used instead of a FM/HM bilayer. The AFM may include a material such as FeMn, IrMn, NiFe, PtMn, NiMn, PtNiMn, Mn, Cr, NiO, CoO or CuMnAs. The FM may include a material such as Co, Fe, Ni, CoFeB Gd, YIG, a ferrite, or alloys comprising Co, Fe, Ni, CoFeB or Gd. The HM may include a material such as Pt, Pd, Ta, W, Pb, Nb, a topological insulator, TMD or a Weyl metal or semimetal.

In general, it should be remembered that the various elements described above may be made from differing materials, implemented in different combinations or otherwise formed or used differently. Example embodiments are not necessarily mutually exclusive as some may be combined with one or more embodiments to form new example embodiments. Figures are not drawn to scale and relative relationships in size may be exaggerated for clarity in presentation. What is claimed is:

1. A spin-orbit torque (SOT)-based magnetic rotary position sensor, comprising:
a first spin Hall anomalous Hall effect (SHAHE) Hall cross formed from a film stack including at least a ferromagnetic (FM)/heavy metal (HM) bi-layer structure capable of generating SOT and having a first current axis, or a first Wheatstone bridge formed from spin Hall magnetoresistance (SMR) or unidirectional spin Hall magnetoresistance (USMR) sensing elements that each include a FM/HM bi-layer structure capable of generating SOT and having a first field sensing axis; and
a second SHAHE Hall cross formed from a film stack including at least a FM/HM bi-layer structure capable of generating SOT and having a second current axis aligned orthogonal to the first current axis of the first Hall cross, or a second Wheatstone bridge formed from SMR or USMR sensing elements that each include a FM/HM bi-layer structure capable of generating SOT and having a second field sensing axis aligned orthogonal to the first field sensing axis of the first Wheatstone bridge.

2. The SOT-based magnetic rotary position sensor of claim 1, wherein the first Hall cross or first Wheatstone bridge is a Hall cross and the second Hall cross or second Wheatstone bridge is a Hall cross.

3. The SOT-based magnetic rotary position sensor of claim 2, wherein each Hall cross includes two current electrodes configured to apply a charge current along the Hall cross's current axis and two voltage electrodes configured to detect voltage change caused by an external field caused in part by current passing through the FM/HM bi-layer structure to generate SOT that induces anomalous Hall effect (AHE) and planar Hall effect (PHE) voltages.

4. The SOT-based magnetic rotary position sensor of claim 2, further comprising:
circuitry configured to measure the AHE and PHE voltages induced by SOT to produce AHE and PHE signals for each Hall cross, isolate the AHE voltage from the PHE voltage to produce a pure AHE signal for each Hall cross, apply an acrtan 2 function to the pure AHE signal for each Hall cross to determine an angle, and output the angle.

5. The SOT-based magnetic rotary position sensor of claim 2, wherein the FM/HM bi-layer structure of the first Hall cross and the second Hall cross use a FM that includes a material selected from the group consisting of cobalt (Co), iron (Fe), nickel (Ni), Cobalt-iron-boron (CoFeB), gadolinium (Gd), yttrium-iron- garnet (YIG), and a ferrite, and the HM material includes a material selected from the group consisting of platinum (Pt), palladium (Pd), tantalum (Ta), tungsten (W), lead (Pb), niobium (Nb), a topological insulator, a transition metal dichalcogenide (TMD), and a Weyl metal or semimetal.

6. The SOT-based magnetic rotary position sensor of claim 1, wherein the first Hall cross or first Wheatstone bridge is a Wheatstone bridge formed from four SMR sensing elements and the second Hall cross or second Wheatstone bridge is a Wheatstone bridge formed from four SMR sensing elements.

7. The SOT-based magnetic rotary position sensor of claim 6, wherein each Wheatstone bridge includes two current electrodes configured to apply a sensing/bias current along the Wheatstone bridge's field sensing axis and two voltage electrodes configured to register a voltage change caused by an external field, wherein the sensing/bias current generates a SOT effective field that provides transverse bias, and the voltage change originates from anisotropic magnetoresistance (AMR), SMR, or both.

8. The SOT-based magnetic rotary position sensor of claim 7, wherein the sensing/biasing current is an alternating current, and the circuity is configured to measure voltage change as a DC component or 2^{nd} harmonic of the voltage between the two voltage electrodes of the Wheatstone bridge.

9. The SOT-based magnetic rotary position sensor of claim 7, wherein the sensing/biasing current is an alternating current superimposed with a DC offset, the circuity is configured to measure voltage change as a DC component or 2^{nd} harmonic of the voltage between the two voltage electrodes of the Wheatstone bridge, and the DC offset of the sensing/biasing current is selected to yield a DC offset of the voltage change that is substantially zero.

10. The SOT-based magnetic rotary position sensor of claim 6, further comprising circuitry configured to receive a sine-like waveform of the first Wheatstone bridge and a cosine-like waveform of the second Wheatstone bridge, apply an algorithm to determine an angle from the sine-like waveform and the cosine-like waveform, and output the angle.

11. The SOT-based magnetic rotary position sensor of claim 6, wherein the FM/HM bi-layer structure of the first Wheatstone bridge and the second Wheatstone bridge use a FM that includes a material selected from the group consisting of cobalt (Co), iron (Fe), nickel (Ni), Cobalt-iron-boron (CoFeB), gadolinium (Gd), yttrium-iron-garnet (YIG), and a ferrite, and the HM material includes a material selected from the group consisting of platinum (Pt), palladium (Pd), tantalum (Ta), tungsten (W), lead (Pb), niobium (Nb), a topological insulator, a transition metal dichalcogenide (TMD), and a Weyl metal or semimetal.

12. The SOT-based magnetic rotary position sensor of claim 1, wherein the first Hall cross or first Wheatstone bridge is a Wheatstone bridge formed from USMR sensing elements and the second Hall cross or second Wheatstone bridge is a Wheatstone bridge formed from USMR sensing elements.

13. The SOT-based magnetic rotary position sensor of claim 12, wherein each Wheatstone bridge includes two current electrodes configured to apply a sensing/bias current along the Wheatstone bridge's field sensing axis and two voltage electrodes configured to register a voltage change caused by an external field.

14. The SOT-based magnetic rotary position sensor of claim 12, wherein the FM/HM bi-layer structure of the USMR sensing elements have a FM that includes a material selected from the group consisting of cobalt (Co), iron (Fe), nickel (Ni), Cobalt-iron-boron (CoFeB), gadolinium (Gd), yttrium-iron- garnet (YIG), and a ferrite, and the HM material includes a material selected from the group consisting of platinum (Pt), palladium (Pd), tantalum (Ta), tungsten (W), lead (Pb), niobium (Nb), a topological insulator, a transition metal dichalcogenide (TMD), and a Weyl metal or semimetal.

15. A spin-orbit torque (SOT)-based magnetic rotary position sensor, comprising:
a first spin Hall anomalous effect (SHAHE) Hall cross formed from a film stack including at least a layer structure capable of generating SOT and having a first current axis; and
a second SHAHE Hall cross formed from a film stack including at least a layer structure capable of generating SOT and having a second current axis aligned orthogonal to the first current axis of the first Hall cross;
wherein each Hall cross includes two current electrodes configured to apply a charge current along the respective current axis and two voltage electrodes configured to io register a voltage change caused by an external field.

16. The SOT-based magnetic rotary position sensor of claim 15, wherein current passing through the layer structure generates SOT that induces anomalous Hall effect (AHE) and planar Hall effect (PHE) voltages.

17. The SOT-based magnetic rotary position sensor of claim 16 further comprising:
circuitry configured to measure the AHE and PHE voltages induced by SOT to produce AHE and PHE signals for each Hall cross, isolate the AHE voltage from the PHE voltage to produce a pure AHE signal for each Hall cross, apply an acrtan 2 function to the pure AHE signal for each Hall cross to determine an angle, and output the angle.

18. A spin-orbit torque (SOT)-based magnetic rotary position sensor, comprising:
a first Wheatstone bridge formed from spin Hall magnetoresistance (SMR) or unidirectional spin Hall magnetoresistance (USMR) sensing elements that each include a layer structure capable of generating SOT, the first Wheatstone bridge having a first field sensing axis; and
a second Wheatstone bridge formed from SMR or USMR sensing elements that each include a FM/HM bi-layer structure capable of generating SOT, the second Wheatstone bridge having a second field sensing axis aligned orthogonal to the first field sensing axis of the first Wheatstone bridge,
wherein each Wheatstone bridge includes two current electrodes configured to apply a sensing/bias current along the Wheatstone bridge's field sensing axis and two voltage electrodes configured to register a voltage change caused by an external field.

19. The SOT-based magnetic rotary position sensor of claim 18, wherein the sensing/bias current generates a SOT effective field that provides transverse bias.

20. The SOT-based magnetic rotary position sensor of claim 18, further comprising:
circuitry configured to receive a sine-like waveform of the first Wheatstone bridge and a cosine-like waveform of the second Wheatstone bridge, and apply an algorithm to determine an angle from the sine-like waveform and the cosine-like waveform, and output the angle.
